(19) United States
(12) Patent Application Publication
(10) Pub. No.: US 2024/0380419 A1
(43) Pub. Date: Nov. 14, 2024

(54) CORRECTING ONE OR MORE ERRORS IN A RECEIVED WORD

(71) Applicant: Telefonaktiebolaget LM Ericsson (publ), Stockholm (SE)

(72) Inventors: Guido Carlo FERRANTE, Stockholm (SE); Hugo TULLBERG, Nyköping (SE)

(21) Appl. No.: 18/691,943

(22) PCT Filed: Sep. 15, 2021
(86) PCT No.: PCT/SE2021/050885

§ 371 Date: Mar. 14, 2024

(51) Int. Cl. H03M 13/29; H03M 13/45

(52) U.S. Cl. CPC H03M 13/2906; H03M 13/451

(57) ABSTRACT

Methods and apparatus are provided. In an example aspect, a method of correcting one or more errors in a received word is provided. The received word includes one or more symbol labels. The method includes modifying a first symbol label in the received word to a first alternative symbol label corresponding to a symbol in a symbol constellation that is one of a closest one or more symbols to a symbol corresponding to the first symbol label to form a first modified word, and determining whether the first modified word is a valid codeword.

### TECHNICAL FIELD

Examples of the present disclosure relate to correcting one or more errors in a received word, for example where the received word comprises one or more symbol labels in a symbol constellation.

### BACKGROUND

Forward-error correction (FEC) is a technique in communication whereby a transmitter may encode data to include redundant information. A receiver may use the redundant information to detect or correct a number of errors in the received data. An example of an error correcting code (ECC) used for FEC is low density parity-check (LDPC) codes. These are used in many wireless communication standards, including 5G and Wi-Fi. Message passing (MP), also known as belief propagation, decoding is the usual method to decode LDPC codes. Decoding techniques have traditionally been codeword-centric: once a word is received, the decoding algorithm tries to find a codeword that is close to the received word following an approximate maximum likelihood criterion via message passing.

A decoding strategy, which is noise-centric, has been proposed in K. R. Duffy, J. Li, M. Medard, “Capacity-Achieving Guessing Random Additive Noise Decoding”, IEEE Transactions on Information Theory 65 (7), 4023-4040, 2019 for binary additive noise channels. Guessing random additive noise decoding (GRAND) aims to find the noise sequence introduced by the channel instead of operating on the received word directly. In an example, GRAND consists of three parts:
A noise guesser: This component outputs candidate noise sequences.
A buffer with candidate words: This component stores a multiplicity of candidate codewords. A candidate codeword is the received symbol sequence, called a word, minus the noise sequence generated by the noise guesser.
A code membership function: This component is used to check if candidate codewords are valid codewords.

GRAND also includes an abandonment rule, which is based on reaching a threshold on the number of candidate noise sequences that have been tested. It is unfeasible to check all noise sequences, since their number is exponential in the codeword length. Therefore, after guessing a predetermined number of noise sequences, the decoding is stopped regardless of whether or not one or more valid codewords are found.

The complexity of GRAND is deterministic. The performance of GRAND approaches maximum likelihood for the limit of a large number of guesses, and it has been shown that the abandonment strategy, if not too restrictive, has minimal impact on performance. GRAND is assumed to operate at very low channel error probability. In particular, for a binary symmetric channel, the average number of errors per word is assumed to be a small integer. In the simulation results shown in their papers, such a small integer is at most 1 with very high probability.

Higher-order constellations are common to increase the spectral efficiency of the transmission. Quadrature Amplitude Modulation (QAM) is an often-used constellation. M-QAM is a constellation with M constellation points such that m=log 2(M) bits are transmitted simultaneously. The bit patterns associated with the symbols, constellation points, are referred to as labels. The labeling is often Gray labeled, i.e. adjacent constellation points only differ in one position of the labels. In an example, the QAM constellations defined in 3GPP standards are Gray labeled. The M value is often selected such that it is a power of 4 since this results in a square QAM constellation that permits Gray labeling.

### SUMMARY

For GRAND to be computationally feasible, the number of errors introduced by the channel needs to be small. For example, not only the fraction of errors per word needs to be small, but also the number of errors. With more than two errors per codeword, existing GRAND may become computationally unfeasible, even for short codes.

One aspect of the present disclosure provides a method of correcting one or more errors in a received word, wherein the received word comprises one or more symbol labels. The method comprises modifying a first symbol label in the received word to a first alternative symbol label corresponding to a symbol in a symbol constellation that is one of a closest one or more symbols to a symbol corresponding to the first symbol label to form a first modified word. The method also comprises determining whether the first modified word is a valid codeword.

A further aspect of the present disclosure provides apparatus for correcting one or more errors in a received word. The apparatus comprises a processor and a memory. The memory contains instructions executable by the processor such that the apparatus is operable to modify a first symbol label in the received word to a first alternative symbol label corresponding to a symbol in a symbol constellation that is one of a closest one or more symbols to a symbol corresponding to the first symbol label to form a first modified word, and determine whether the first modified word is a valid codeword.

An additional aspect of the present disclosure provides apparatus for correcting one or more errors in a received word. The apparatus configured to modify a first symbol label in the received word to a first alternative symbol label corresponding to a symbol in a symbol constellation that is one of a closest one or more symbols to a symbol corresponding to the first symbol label to form a first modified word, and determine whether the first modified word is a valid codeword.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 is a flow chart of an example of a method of correcting one or more errors in a received word;

FIG. 2 shows an example of a 64QAM constellation;

FIG. 3 shows examples of symbols in a QAM constellation;

FIG. 4 shows an example of a system for correcting one or more errors in a received word;

FIG. 5 shows an example of graphs of the number of guesses needed, in the worst case, to correct h errors as a function of the block length for 256QAM;

FIG. 6 shows an example of graphs of the number of guesses needed, in the worst case, to correct h errors as a function of the block length for 4096QAM;

FIG. 7 shows an example of graphs of the number of guesses needed, in the worst case, to correct h errors as a function of the modulation order for a block length of n=120;

FIG. 8 shows an example of graphs of the number of guesses needed, in the worst case, to correct h errors as a function of the modulation order for a block length of n=240; and

FIG. 9 is a schematic of an example of an apparatus 900 for correcting one or more errors in a received word.

### DETAILED DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analogue) circuitry including but not limited to application specific integrated circuit(s) (ASIC) and/or field programmable gate array(s) (FPGA(s)), and (where appropriate) state machines capable of performing such functions.

A key component of the GRAND decoding algorithm discussed above is the noise guesser. In the prior art, the noise guesser is only described in general terms, and mostly for binary channels. For higher-order modulation, guessing the noise for the binary codeword does not make use of the properties of the signal constellation.

Proposed herein are methods and apparatus that may in some embodiments solve one or more of the above-mentioned problems. In some examples, techniques disclosed herein may be used to implement a GRAND noise guesser adapted to higher-order, Gray-labeled signal constellations. For example, methods as disclosed herein (e.g. in a GRAND noise guesser) may use one or more symbols that are closest to a received symbol to guess noise that has affected a received symbol (e.g. a symbol that is in a received invalid codeword).

Thus, for example, complexity of GRAND decoding may be reduced by incorporating the knowledge of modulation and labeling into the noise guesser. The complexity saving with respect to a GRAND decoder that does not use the knowledge about modulation and labeling increases with increasing constellation size and number of errors to correct. Therefore, for example, this may either extend the application of embodiments of this disclosure for more challenging channel conditions, or may have the same performance as traditional GRAND with fewer computations.

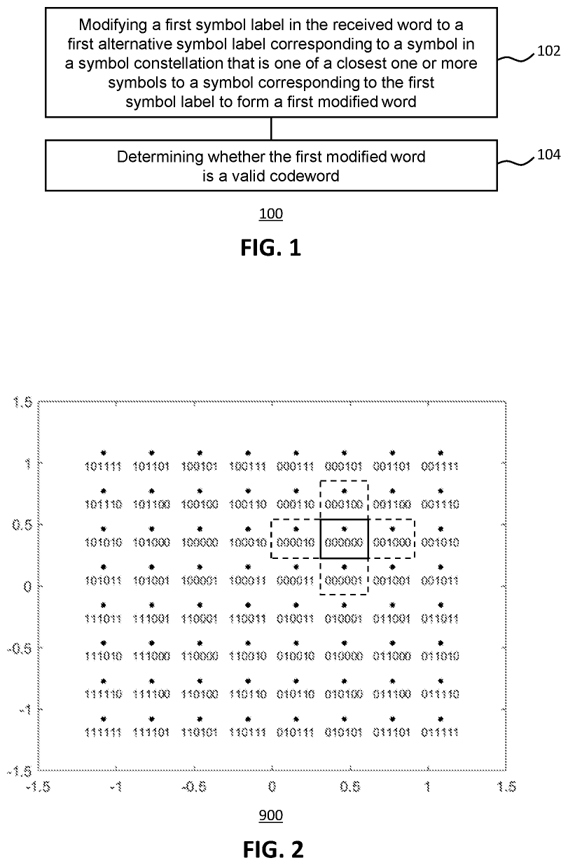

FIG. 1 is a flow chart of an example of a method 100 of correcting one or more errors in a received word, wherein the received word comprises one or more symbol labels. The symbol labels may for example correspond to symbols in a symbol constellation. For example, where the received word contains s symbol labels (corresponding to s symbols), and each symbol in the symbol constellation represents m bits, the received word has ms bits. In some examples, the method 100 may be performed when the received word is not a valid codeword.

The method 100 comprises, in step 102, modifying a first symbol label in the received word to a first alternative symbol label corresponding to a symbol in a symbol constellation that is one of a closest one or more symbols to a symbol corresponding to the first symbol label to form a first modified word. The symbol constellation comprises symbols that may be transmitted or received, each symbol having a different amplitude and/or phase. Different symbols may convey different information. For example, particular symbols may represent certain values of a number transmitted bits in some examples.

The symbol constellation may comprise for example a Quadrature Amplitude Modulation (QAM) constellation. Examples of QAM constellations include a square QAM (SQAM) constellation such as 16QAM, 64QAM, 256QAM, 1024QAM, 4096QAM and other orders of QAM constellation. Alternatively, for example, the symbol constellation may comprise other shapes of constellation such as cross or circular shapes, or may alternatively comprise a different type of constellation such as Phase Shift Keying (PSK). Examples described below are described in the context of a 64QAM constellation, though the principles disclosed herein may also apply to other symbol constellations in other examples.

FIG. 2 shows an example of a 64QAM constellation 200 that has 64 symbols, each having a label representing six bits. Each symbol is shown as a dot or point on the constellation. Each symbol represents a particular value for amplitude and phase of a received signal. A solid box is shown around a particular symbol representing the bits 000000, and this symbol may be a symbol in a received word in an example. Dashed boxes are shown around the four closest symbols which have the symbol labels 000100, 000010, 001000 and 000001 respectively. These are the closest four symbols to the symbol label (the first symbol label) of the received symbol, and are the symbols that are vertically and horizontally adjacent to the first symbol label in this example. Thus, the closest one or more symbols to the symbol corresponding to the first symbol label (000000 in this example) may include one or more of these four symbols in some examples. In other words, for example, the closest one or more symbols to the symbol corresponding to the first symbol label may comprise at least one of one or both symbols vertically adjacent to the symbol corresponding to the first symbol label in the QAM constellation; and/or one or both symbols horizontally adjacent to the symbol corresponding to the first symbol label in the QAM constellation. (Note that for symbols at edges or corners of the QAM constellation, some of these symbols may not be present. For example, the top-left symbol in the QAM constellation 200 shown in FIG. 2, corresponding to label 101111, has only one vertically adjacent symbol 101110 and one horizontally adjacent symbol 101101.) In some examples, the closest one or more symbols may include even more symbols, such as in this example, for the symbol 000000, one or more of those with symbol labels 000110, 001100, 000011 and 001001, and in some examples even more symbols.

Thus for example the method 100 determines a first modified word including the first alternative symbol label in place of the first symbol label. The method 100 then comprises, in step 104, determining whether the first modified word is a valid codeword. If the first modified word is a valid codeword, then for example the method 100 has likely been successful in guessing the symbol that was transmitted and that was (incorrectly) received as the first symbol label, assuming for example that the received word includes a small number of errors (e.g. one).

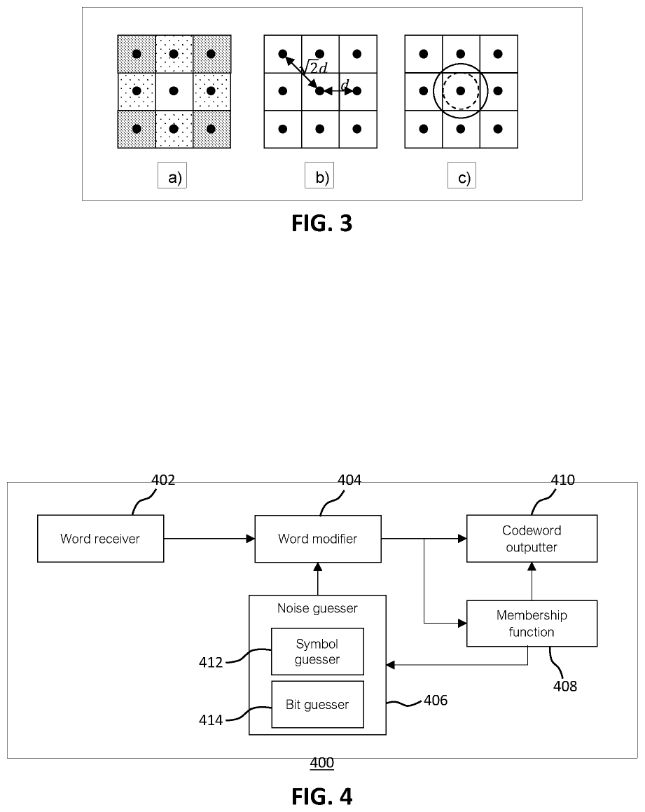

FIG. 3 shows examples of symbols in a QAM constellation. FIG. 3(a) shows examples of nine symbols including a central symbol (which may be for example the symbol corresponding to symbol label 000000 shown in FIG. 2) and the eight closest symbols, including the four horizontally and vertically adjacent symbols and the four next closest symbols (corresponding to the symbols at the “corners” of the central symbol). If the central symbol is transmitted, then the symbol is received with zero errors if the received symbol has an amplitude and phase that falls within the square surrounding the central symbol. In some examples of QAM constellations and their corresponding labels (including the QAM constellation 200 shown in FIG. 2), the symbol label corresponding to the received symbol has one bit error if the received symbol falls in any of the dotted regions (i.e. the square regions around the vertically and horizontally adjacent symbols to the received symbol), and two errors in any of the gray regions (corresponding to the corner symbols).

FIG. 3(b) illustrates the distance between the central symbol and two of the other symbols. The distance between the center of the region containing the central symbol, which corresponds to a transmitted symbol in this example, and a nearest symbol to the center of the region containing the received symbol, which is one of the horizontally adjacent symbols in this example, corresponds to one bit error and is shown as d in this example. On the other hand, the distance from the transmitted symbol and a corner symbol, corresponding to two bit errors, √2d. FIG. 3(c) illustrates regions in which a symbol can be received. To lower-bound the probability of making more than 1 error, the center symbol is enclosed within a circle of radius √2d/2 (solid circle), and thus a symbol outside of this circle (and within a square surrounding one of the vertically or horizontally adjacent symbols) has a label that has at least one bit error. This bound is loose since the true area where at most one error occurs is the white and dotted squares in FIG. 3(a) (i.e. the central box and the four left/right and up/down adjacent boxes). FIG. 3(c) also shows a dashed circle within the central box. If the central symbol is transmitted and the received symbol is within the dashed circle, then the symbol is interpreted as being the central symbol and therefore the corresponding bits have no error.

In some examples, the closest one or more symbols to the symbol corresponding to the first symbol label comprise a plurality of symbols closest to the symbol corresponding to the first symbol label (e.g. the four symbols surrounded by dashed boxes in FIG. 2). The method 100 may then further comprises, in some examples, if the first modified word is not a valid codeword, for each of one or more further symbols of the plurality of symbols closest to the symbol corresponding to the first symbol label, modifying the first symbol label in the received word to a respective further alternative symbol label corresponding to the further symbol to form a respective further modified word, and determining whether the respective further modified word is a valid codeword. In other words, in some examples, each of the closest symbols are used to modify the first symbol in turn to attempt to produce a valid modified codeword.

In some examples, this may be performed in an order based on soft decoding information, such as for example a Log Likelihood Ratio (LLR), for the first symbol label. For example, the order comprises an order of decreasing likelihood for each of the first alternative symbol label and the further alternative symbol labels. In other words, for example, referring to FIG. 2, the soft decoding information for the received symbol with the label 000000 may indicate that the received symbol (which may not have amplitude and/or phase exactly for the symbol with the symbol label 000000) is closer to the symbol with label 000010 than 001000, for example, and hence the symbol label 000010 may be used to produce the modified codeword before the symbol label 001000.

In other examples, this may be performed in an order based on decreasing probability that one or more respective bits in the first symbol label modified to the first alternative symbol label and each of the further alternative symbol labels correspond to the one or more errors in the received word. For example, referring to FIG. 2, it is noted that the symbols in the left half of the QAM constellation 200 have 1 as the first bit of their symbol labels, whereas those in the right half have 0 as the first bit. Similarly, the symbols in the top half of the QAM constellation 200 have 0 as the second bit of their symbol labels, whereas those in the bottom half have 1 as the first bit. Therefore, these first and second bits may be considered as having a lower probability of being in error than other bits in the symbol, as in some examples a much larger deviation must be caused to the received symbol from the transmitted symbol to cause these bits to be in error. This is an example, and in other examples, the probabilities of certain bits being in error may be determined using other means.

A property of the Gray labeling is that in some examples, with high probability, only one bit-error occur per transmitted symbol. This is because for example it is most likely that a symbol affected by noise is incorrectly interpreted as an adjacent symbol (e.g. the nearest symbol vertically or horizontally in the symbol constellation) than another symbol. Hence for the method 100, symbol label(s) corresponding to the closest one or more symbols to the received symbol are first used as the modified symbol. Furthermore, the label may in some examples be such that the bits in the label have unequal error probability, as indicated above. The noise guesser thus first guesses which symbols may be in error (e.g. based on CSI) and then which bit is in error (e.g. from the symbol constellation) in order of descending probability.

In some examples, if all of the one or more closest symbols are used to form respective modified codewords, but no valid codeword is found, then the method 100 may comprise, for each of one or more additional symbol labels in the symbol constellation, modifying the first symbol label in the received word to the additional symbol label to form a respective further modified word, and determining whether the respective modified word is a valid codeword. In other words, for example, other symbol label(s) may be used to attempt to find a valid codeword if using the symbol labels corresponding to the closest symbol(s) does not find a valid codeword. In some examples, this may correspond to a traditional GRAND technique (excluding the closest one or more symbols to the symbol corresponding to the first symbol label).

In some examples, the received word comprises a plurality of symbol labels, e.g. the received word has ms bits, where the number s of symbol labels in a word n>1. The method may therefore comprise, if the first modified word is not a valid codeword, for each of one or more further symbol labels in the received word, modifying the further symbol label to a respective alternative symbol label corresponding to a symbol the symbol constellation that is one of a closest one or more symbols to a symbol corresponding to the further symbol label to form a respective further modified word, and determining whether the respective further modified word is a valid codeword. In other words, for example, another one of the symbol labels in the received word may be modified to attempt to find a valid codeword. The other symbol label may be modified according to any of the techniques described above in some examples. In some examples, if still no valid codeword is found, other symbol labels may be so modified as well in order to attempt to find a valid codeword.

The closest one or more symbols to the symbol corresponding to the further symbol label may for example comprise a plurality of symbols closest to the symbol corresponding to the further symbol label. Thus, the method 100 may further comprise, if the further modified word is not a valid codeword, for each of one or more further symbols of the plurality of symbols closest to the symbol corresponding to the further symbol label, modifying the further symbol label in the received word to a respective further alternative symbol label corresponding to the further symbol to form a respective further modified word, and determining whether the respective further modified word is a valid codeword. Modifying the further symbol label to the alternative symbol label and each of the further alternative symbol labels is performed in an order based on soft decoding information (e.g. LLRs) for the further symbol label, for example as suggested above for the first symbol label. The order may comprise for example an order of decreasing likelihood for each of the alternative symbol label and the further alternative symbol labels. Alternatively, for example, modifying the further symbol label to the alternative symbol label and each of the further alternative symbol labels is performed in an order based on decreasing probability that one or more respective bits in the further symbol label modified to the alternative symbol label and each of the further alternative symbol labels correspond to the one or more errors in the received word. If each of the further modified words is not a valid codeword, for each of one or more additional symbol labels in the symbol constellation, modifying the further symbol label in the received word to the additional symbol label to form a respective further modified word, and determining whether the respective further modified word is a valid codeword.

The order in which to modify symbol labels in a received word may be chosen based on certain information in some examples. For example, for fading channels, channel state information (CSI) may be used to determine the order, e.g. symbol labels that correspond to time periods where fading dips are detected may be selected for modification first. In other examples, however, where an error to any of the symbol labels in a word is equally likely as for additive white Gaussian noise (AWGN) channels, the order may be selected in other ways, e.g. sequentially or randomly.

In some examples, modifying the first symbol label in the received word to the first alternative symbol label may comprise generating a noise bit sequence, and combining the noise bit sequence (e.g. by subtraction) from the received word to form the first modified word. Thus for example implementations of the method 100 may use components that are similar to those used in GRAND implementations. FIG. 4 shows an example of a system 400 for correcting one or more errors in a received word, and may in some examples perform the method 100. The system 400 includes a word receiver 402 that receives a word and provides the received word to a word modifier 404. The word modifier 404 receives a noise sequence from noise guesser 406 and applies it to the received word, hence forming the modified word. The modified word is provided to membership function 408 and codeword outputter 410. The membership function 408 determines if the modified word is a valid codeword, and if so, indicates to the codeword outputter 410 to provide the modified codeword to other components (not shown). If, however, the modified word is not a valid codeword, then the membership function 408 informs the noise guesser 406 to try a different noise sequence and hence a different modified word is produced and provided to the membership function 408 and codeword outputter 410.

The noise guesser 406 may in some examples generate noise sequences in such a manner so as to implement any of the examples of the method 100 described herein. Thus, the noise guesser 406 may in some examples have knowledge of the locations of symbol labels in the received word, and also may have knowledge of the symbol constellation used to transmit those symbols (e.g. QAM constellation 200 shown in FIG. 2). In the example shown in FIG. 4, the noise guesser 406 includes symbol guesser 412 and bit guesser 414. The symbol guesser 412 may for example generate noise sequences for one or more particular labels in the received word, and the bit guesser 414 may for example indicate to the symbol guesser the order in which alternative symbol labels should be used (e.g. in order of decreasing likelihood or decreasing bit error probability as suggested above). The process may continue for example until either a codeword is found or the number of iterations exceeds some threshold, in which case the process is terminated or abandoned, and the received word may be outputted as an invalid codeword (which may in some examples be corrected using some other method, or a retransmission request may be sent for data including that word).

In some examples, the system 400 simply passes the received word to the codeword outputter 410 and membership function 408 without modification, to determine if the received word is a valid codeword, before modification is performed in accordance with the method 100 for example. This may be done for example by the noise guesser 406 first outputting a sequence of all O's as the noise sequence. In other examples, however, the received word may have already been determined as not being a valid codeword and hence contains errors (i.e. only invalid received words are provided to the word receiver 402).

In some examples, the symbol guesser 412 may be based on the following observation. For a given signal to noise ratio (SNR) at a receiver, the modulation and coding scheme (MCS) selection may guarantees that the number of errors per codeword is relatively small. This may be achieved, for example, by selecting an appropriate modulation order such that, for the given channel SNR, the received signal is close to the constellation points. When the noise causes a received symbol to move outside of the decision region of the transmitted symbol (e.g. the square region around each symbol as shown in FIG. 3), it typically moves the symbol to an adjacent decision region, e.g. along the axes. For example, if the transmitted symbol were 000000, strong noise makes the signal move to one of the doted regions shown in FIG. 3(a). as shown below, the probability of moving to symbols on the diagonal (e.g. the grey shaded regions shown in FIG. 3(a)) is exponentially smaller than moving to symbols vertically or horizontally. In FIG. 3(c), a region of a QAM constellation is depicted with two circles, one with solid border and one with dashed border. As long as the noise is within the circle with dashed border, no error occurs. When noise is in between the two circles, there may be a single error; this event accounts for most of the probability of single errors in some examples, even though the regions in the solid circle that are outside the central square appear to be small compared to the regions where single errors can occur, e.g. the dotted regions in FIG. 3(a). In some examples, there may be a 2D Gaussian distribution centered on the central symbol in FIG. 3, and the tails of the Gaussian distribution decrease exponentially rapidly. This is why the majority of single errors does not happen outside the solid circle in some examples.

It follows that, if there is an error in the label, it is likely that the label is one of those corresponding to the four closest, adjacent symbols which comprise the vertically and horizontally adjacent symbols. Note that, if the fraction of bits in error per codeword is typically few, the fraction of symbols in error is even lower.

GRAND decoders assume that the number of bits in error per codeword is small both in absolute value and relative to the codeword length. For example, five errors in a codeword may be regarded as a large number for any codeword length. Furthermore, the codeword length n (where n may be equal to ms in the examples described above) needs to be relatively small. This is because a GRAND decoder that is unaware of the code and the modulation/labeling used needs about n\hat{ }k guesses to identify a noise sequence of weight k, that is a noise sequence that flipped k bits. These GRANDs are referred to as universal, since they can be used on any code (even though the membership function is always code-specific). Embodiments of this disclosure may for example save a significant fraction of guesses with respect to such a universal GRAND, as illustrated below.

Suppose the received word consists of n/m labels each of length m bits for a total of n bits (where n/m=s for the examples described above). In order to identify a single error, a universal GRAND would flip each bit and check whether the modified word is a codeword or not. Embodiments of this disclosure may for example flip one bit per symbol as follows: first, fix a symbol (there are n/m ways to fix the symbol); second, flip the bit that changes going from the received symbol to the four horizontally and vertically adjacent symbols, for example by modifying the symbol or providing the appropriate noise sequence.

For guessing up to one bit error per symbol, the number of guesses is, in the worst case, given by

$$( \begin{matrix}n / m \\ 1\end{matrix} ) 4 ,$$

which needs to be compared to

$$( \begin{matrix}n \\ 1\end{matrix} ) = n$$

for the universal GRAND discussed above. Therefore, the computational saving is (at least) m/4, that is, the higher the modulation order the better the computation saving. The actual computational saving may in some examples be slightly higher because edge and corner symbols can be treated differently than internal symbols. Specifically, edge symbols can be in error in only three ways, and hence only three modified symbols instead of four need to be tested for such received symbols. Similarly, corner symbols can be in error in only two ways. In both of these cases, only horizontal and vertical adjacent symbols are considered, which as shown below may be exponentially more likely than diagonal moves.

When two errors occur in the codeword, in some embodiments, it can be assumed that these occur in different symbols. Additionally or alternatively, in examples of this disclosure, after the closest one or more symbols to a received symbol are tested (for one or more symbols in the received word as appropriate), all the remaining noise sequences may be tested as GRAND would do. Thus, embodiments of this disclosure may always perform at least as well as GRAND, but the order of the noise sequences that are guessed or tested is in accordance with examples described herein, which is in some examples the reason for the computational savings because the noise sequences are not equally likely. Therefore, assuming that the two errors come from different symbols, then the maximum number of guesses needed to identify the two errors in a received word (with the assumption of at most one error per symbol) is

$$( \begin{matrix}n / m \\ 2\end{matrix} ) {4}^{2}$$

because there are

$$( \begin{matrix}n / m \\ 2\end{matrix} )$$

ways to choose the pair of symbols in error and there are 4 ways to choose the bit in error per each symbol in error. This number of guesses needs to be compared with

$$( \begin{matrix}n \\ 2\end{matrix} )$$

in universal GRAND. The computational saving is (m/4)², that is, for more errors the saving is larger.

In general, in some examples, when there are h errors, we select first h-tuples of symbols and then the four possible bits per symbol that could be in error. The number of guesses in the worst case are

$$( \begin{matrix}n / m \\ h\end{matrix} ) {4}^{h}$$

rather than

$$( \begin{matrix}n \\ h\end{matrix} )$$

in universal GRAND.

It will now be shown that in particular examples the probability of making two or more errors is much less than making no error or one error only. If this is true, then noise affecting a received symbol enough such that the received symbol is interpreted as diagonally adjacent to the transmitted symbol (e.g. one of the corner symbols shown in FIG. 3), which would imply two or more errors, is much less likely than a horizontally adjacent symbol, which implies one error, or a symbol within the correct decision region (e.g. the square surrounding the central symbol ion FIG. 3), which implies no error. That is, we want to show that:

$$\frac{P [ \# errors \geq 2 ]}{P [ \# errors \leq 1 ]} {\to }^{d \to ∞} 0$$

The limit holds for sufficiently high SNR, which is guaranteed by MCS in some examples.

We derive first an upper bound on the numerator and a lower bound on the denominator so as to upper bound the ratio. If the bound goes to zero, then surely also the ratio goes to zero. The main observation is that the numerator is represented by the gray region in FIG. 3(a) (and in some examples all the regions in the QAM constellation not shown in FIG. 3). The area of such a region is smaller than the area of the region outside the solid circle in FIG. 3(c), and thus:

$$P [ \# errors \geq 2 ] \leq P [ 𝒩 ( 0 , I ) ∉ {ℬ}_{0} ( \sqrt{2} d / 2 ) ] = {e}^{- {d}^{2} / 4}$$

where [symbol] (0, I) denotes a bidimensional Normal distribution with zero mean and identity covariance, and [symbol] ₀ (\sqrt{2}d/2)] denotes the ball of center in zero and radius \sqrt{2d}/2 i.e. the area inside the solid circle in FIG. 3(c).

Similarly, the denominator of the fraction we want to bound is given by the union of white and dotted regions in FIG. 3(a). Such an area is larger than the area inside the solid circle in FIG. 3(c), and thus:

$$P [ \# errors \leq 1 ] \geq P [ 𝒩 ( 0 , I ) ∈ {ℬ}_{0} ( \sqrt{2} d / 2 ) ] = 1 - {e}^{- {d}^{2} / 4} .$$

Therefore, the ratio is upper bounded as follows:

$$\frac{P [ \# errors \geq 2 ]}{P [ \# errors \leq 1 ]} \leq \frac{{e}^{- {d}^{2} / 4}}{1 - {e}^{- {d}^{2} / 4}} \approx {e}^{- {d}^{2} / 4} \qquad ( 1 )$$

This quantity goes to zero exponentially fast as d increases, which implies that making two or more errors is exponentially less likely than making no error or one error.

In the above derivation, d² is proportional to SNR. In particular, the SNR attained by a 2^{m}-QAM where constellation points are uniformly spaced by d is given by:

$$SNR = \frac{\frac{{d}^{2}}{6} ( {2}^{m} - 1 )}{2}$$

where the numerator is the power (variance) of the constellation and the denominator is the variance of the noise (notice that since we used [symbol] (0, I) as noise distribution, then the real and imaginary parts of the noise both have variance 1, and thus the complex noise has variance 2). Since:

$$SNR = \frac{E [ {‖ {X}^{ℓ} ‖}^{2} ]}{E [ {‖ {Z}^{ℓ} ‖}^{2} ]} = \frac{ℓ {mE}_{b , c}}{ℓ {N}_{0}} = \frac{{RmE}_{b}}{{N}_{0}} ,$$

where [symbol] and [symbol] denote the length- [symbol] codeword and noise sequence, E_{b,c} and E_{b} denote the energy per coded bit and information bit, respectively, and R represents the rate, then:

$${d}^{2} = \frac{12}{{2}^{m} - 1} Rm \frac{{E}_{b}}{{N}_{0}} .$$

Therefore, d² is proportional to E_{b}/N₀, and thus equation (1) above indicates that for large enough E_{b}/N₀, the occurrence of two errors is exponentially less likely than the occurrence of up to one error.

To get an estimate that is more accurate than (1), let us proceed numerically. The probability of making no error or one error is given by the volume of a Gaussian over the white and dotted squares in FIG. 3(a). Suppose that 64-QAM (m=6 coded bits per symbol) is used to transmit 128-bit LDPC codewords each encoding 64 bits (R=½) by means, for example, of a Consultative Committee for Space Data Systems (CCSDS) code (BLER≈10⁻⁵ at E_{b}/N₀≈5 dB). Notice that the choice of CCSDS code is not crucial and changing the code would only slightly change the value of E_{b}/N₀. In the above scenario, it results in d\hat{ }2≈1.8. Numerically, we can evaluate the probability of making more than one error via Monte Carlo simulations, which results in an error probability of ≈0.135.

In some examples of this disclosure, symbol labels in received words can be tested where there are up to two errors per label, and the process may be terminated, for example where there may be three or more errors in a symbol or word. This is a less likely situation than the case of one error; for example, in the above scenario, this may occur with probability≈4.8×10⁻⁵.

Two bit errors in a symbol are most likely to come from symbols on the diagonal (e.g. the grey squares shown in FIG. 3(a))), therefore the number of guesses needed, in the worst case, to recover from an error coming from h incorrect symbols with two errors each is most likely equal to

$$( \begin{matrix}n / m \\ h\end{matrix} ) {4}^{h} .$$

Generally, there may be 8 possible 2-error symbols surrounding the transmitted symbol (unless the symbol is close to the edges of the constellation), and thus the worst-case scenario is to check

$$( \begin{matrix}n / m \\ h\end{matrix} ) {8}^{h}$$

labels. Since not all symbols are equally likely, guesses should be done in order of likelihood, which is: diagonal 2-error-bearing symbols first (gray squares in FIG. 3a); vertical and horizontal 2-error-bearing symbols then (not depicted in FIG. 3; they are two squares away from the transmitted symbol, i.e., the white square, horizontally and vertically). This needs to be compared with GRAND recovering 2h errors, which requires about

$$( \begin{matrix}n \\ 2 h\end{matrix} )$$

guesses.

Finally, notice that the above algorithms can also be extended to the general case where a number of bits in error are spread over h symbols in a received word. Some symbols carry one erroneous bit, others two erroneous bits, etc. In general, symbol i may carry wᵢ erroneous bits. As we pointed out above, the probability that wᵢ=W decreases with increasing W. That is, W=0 is the most likely event (no error), followed by W=1, etc. Since wᵢ is not known, one needs to cap the maximum number of errors per symbol to check, say wₘₐₓ. If maxᵢ wᵢ>wₘₐₓ then the process may fail to find a valid codeword, and message passing will be called in some examples.

In an example general case, the algorithm starts by guessing which of the h symbols in a word may be incorrect, then flips 1 bit in each symbol, then 1 bit in all but one symbol where it flips 2 bits, then 1 bit in all but two symbols where it flips 2 bits, and so on until flips wₘₐₓ bits in all h symbols. Therefore, the number of guesses, provided that h is known, is in the worst case given by:

$$( \begin{matrix}n / m \\ h\end{matrix} ) {\prod }_{i = 1}^{h} {\sum }_{{w}_{i} = 1}^{{w}_{max}} ( \begin{matrix}m \\ {w}_{i}\end{matrix} )$$

If h is not known, as usually is the case, then the algorithm starts from h=1 up to h=hₘₐₓ

$${\sum }_{h = 1}^{{h}_{max}} ( \begin{matrix}n / m \\ h\end{matrix} ) {\prod }_{i = 1}^{h} {\sum }_{{w}_{i} = 1}^{{w}_{max}} ( \begin{matrix}m \\ {w}_{i}\end{matrix} )$$

This needs to be compared to

$${\sum }_{w = 1}^{{h}_{max} {w}_{max}} ( \begin{matrix}n \\ w\end{matrix} ) \approx ( \begin{matrix}n \\ {h}_{max} {w}_{max}\end{matrix} )$$

guesses needed by GRAND for recovering hₘₐₓwₘₐₓ errors.

Note that in described embodiments where one bit error occurs in vertically or horizontally adjacent symbols and two bit errors occur for diagonal/corner symbols, these apply where the labels for symbols in a symbol constellation are Gray labelled. However, the concepts disclosed herein can be extended to those constellations where the symbols are not Gray labelled. For example, the vertically and horizontally adjacent symbols may be tested in some examples (and the diagonal ones next in some examples), regardless of the number of bits in a symbol need to be changed to modify that symbol.

If we know the received symbol (more precisely, the constellation symbol closest to the received symbol), we can determine which bits should be modified or flipped to result in the symbol labels of the nearest neighbors. For example, if we receive a symbol with the label 000000 in the QAM constellation 200 shown in FIG. 2, then each of the four right-most bits should be flipped to arrive at the four nearest neighbors (one bit should be flipped to result in each of the vertically and horizontally adjacent symbols). If we instead receive a symbol corresponding to the label 000001 at the bottom of the cross, we should not flip the second bit from the right but instead the second bit from the left. Similarly, which bits to flip to result in the vertically and horizontally adjacent symbols (where they are present) may be determined for all symbols in the symbol constellation. Such information can be provided as a look up table such that embodiments of this disclosure may flip the appropriate bits to determine the modified symbol labels of the closest one or more symbols to a received symbol. An example of such a lookup table is shown below, and corresponds to a subset of the symbols in the QAM constellation 200 shown in FIG. 2:

| Constellation | Bits in label to flip | |
|---|---|---|
| label | (b₁b₂b₃b₄b₅b₆) | Comment |
| 000000 | 3, 4, 5, 6 | |
| 000001 | 2, 3, 5, 6 | |
| 110011 | 1, 2, 5, 6 | |
| 111010 | 4, 5, 6 | Edge point |
| 101111 | 5, 6 | Corner point |

If we do not want to keep track of which symbol was received, we can use the properties of the Gray labeling to determine a probabilistic guessing order in some examples. In the constellation 200 shown in FIG. 2, the first, third and fifth bit from the left determine the position along the x-axis. (The x and y axes are independent in a QAM constellation, so the same argument holds for the y axis. The labels are in fact two independent 3-bit labels.) The fifth bit changes four times, the third bit twice and the first bit only once. The pattern is analogous for larger constellations; the most frequently changing bit changes twice as often as the second-most changing, which in turn changes twice as often as the third-most changing, and so forth. Based on this observation, we can use a symbol-independent bit-flipping pattern where we flip the bits in order of descending flip probability. For the constellation in FIG. 2, in an example, we would first flip the two rightmost bits, then the middle two bits, and lastly the two leftmost, where all bits are flipped one at the time. This method requires up to m flips per label but does not require any table lookup to find the labels of the nearest neighbors. Thus, for example, such information may correspond to the probability discussed above that one or more respective bits in the first symbol label modified to the first alternative symbol label and each of the further alternative symbol labels correspond to the one or more errors in the received word.

Consider one axis, the number of flips in the label is a geometric distribution. As the number of bits in the label per axis, m/2, tends to infinity the expected number of flips per axis approaches 2. For a 2D QAM constellation the expected value tends to 4, so even if we do not consider the actual transmitted value, the expected number of guesses is still 4, which is equal to the worst case for known transmitted value.

If an interleaver is used in the system, in some examples, coded bits are permuted before transmission. The noise guesser in some examples may then act on the symbols and bits in the received order, and the membership function may act on the symbols in the deinterleaved sequence, with appropriate interleaving and deinterleaving in between. Thus the interleaving function does not change the ability of disclosed embodiments to correct errors, but we have to keep track of the indices. To avoid multiple deinterleaving operations, in an example, the indices corresponding to different symbols and bits can be pre-tabulated. The m indices corresponding to a symbol is deinterleaved and stored. In the table the indices may be listed in order of descending probability.

For example, consider a transport block of length 36 bits corresponding to six 64-QAM symbols and a given interleaver. An example of such a table may then be that shown below:

| | | Deinterleaved | Deinterleaved |
|---|---|---|---|
| | Original indices in | indices in transport | indices in order of |
| Symbol | transport block | block | descending flip |
| number | (b₁b₂b₃b₄b₅b₆) | (b₁b₂b₃b₄b₅b₆) | probability |
| 1 | 1, 2, 3, 4, 5, 6 | 3, 32, 10, 15, 7, 28 | 7, 28, 10, 15, 3, 32 |
| 2 | 7, 8, 9, 10, 11, 12 | 6, 25, 26, 16, 14, 17 | 14, 17, 26, 16, 6, 25 |
| 3 | 13, 14, 15, 16, 17, | 35, 8, 31, 2, 1, 29 | 1, 29, 31, 2, 35, 8 |
| | 18 | | |
| 4 | 19, 20, 21, 22, 23, | 27, 34, 11, 22, 30, | 30, 20, 11, 22, 27, |
| | 24 | 20 | 34 |
| 5 | 25, 26, 27, 28, 29, | 12, 21, 9, 19, 4, 13 | 4, 13, 9, 19, 12, 21 |
| | 30 | | |
| 6 | 31, 32, 33, 34, 35, | 33, 24, 23, 5, 18, 36 | 18, 36, 23, 5, 33, 24 |
| | 36 | | |

This information may be used for example by the membership function without a deinterleaving operation being performed to determine whether the received word is a valid codeword, or alternatively for example by the noise guesser to modify certain symbol(s) in a word after a deinterleaving operation has been performed.

A particular example of how the above table can be used will now be described, and where the received word is deinterleaved before error correction. The algorithm will consecutively select symbols 1 through 6, and then flip bits within the symbols. In a first option: Use the above table to get the indices in the deinterleaved sequence that makes up the symbol label (third column). For symbol 1, get the bits from positions 3, 32, 10, 15, 7, and 28 in the deinterleaved sequence. The values of these bits point out which symbol was received, e.g., “110011”. Use Table 1 to get the bits in the labels to flip to get the labels of the nearest neighbors, here 1, 2, 5, and 6, which corresponds to indices 3, 32, 7, and 28 in the deinterleaved sequence. Flip one of these bits at the time and check for each flip if the word is a valid codeword. If a valid codeword is found, the process may terminate, otherwise continue to the next bit in the label, and if there are no more bits to flip in the label, then continue to the next symbol.

In a second option: Use Table 2 to get the indices in the deinterleaved sequence that makes up the symbol label but sorted in descending order of flip probability (fourth column). For symbol 1, get the bits from position 7, 28, 10, 15, 3, 32 in the deinterleaved sequence. Flip one of these bits at the time and check for each flip if the word is a valid codeword. If a valid codeword is found, the process may terminate, otherwise continue to the next bit in the label, and if there are no more bits to flip in the label, then continue to the next symbol.

For both options, if no valid codeword was found by flipping bits in the labels of the first symbol, continue to symbol 2. If no codeword was found by flipping one bit in the labels, we increase the number of errors to guess to two. We select two symbols at the time, e.g., (1,2), (1,3), . . . , (5,6) and guess bit errors per symbol as described above. The number of errors to guess is increased until we reach a maximum value, in which case the process is terminated.

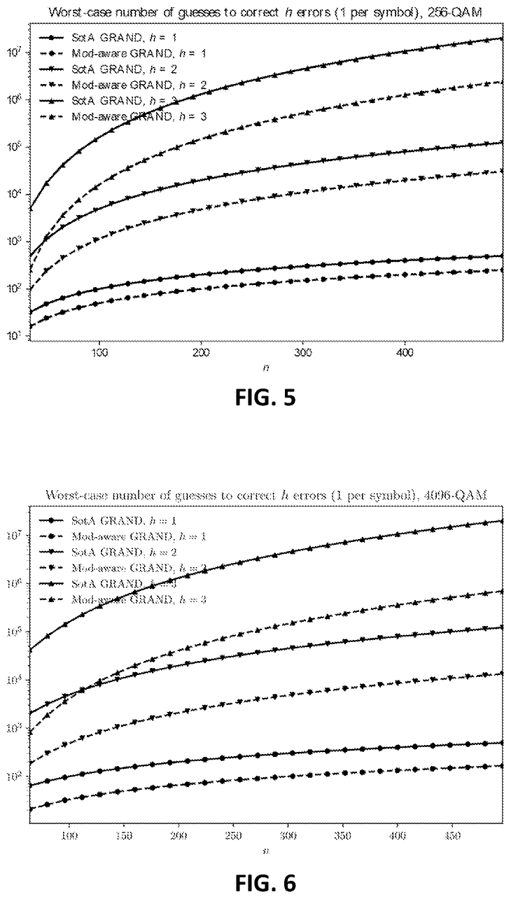

FIGS. 5 and 6 show examples of graphs of the number of guesses needed, in the worst case, to correct h errors as a function of the block length for two different modulation orders, 256QAM for FIG. 5 and 4096QAM for FIG. 6. The graphs show results for example techniques according to this disclosure (labelled as mod-aware GRAND) and the state-of-the-art (SotA) GRAND, which is unaware of modulation and labeling. The saving factor is shown to be approximately constant with respect to the block length and increases as the number of errors to be corrected increases, ranging from 5 to more than one order of magnitude.

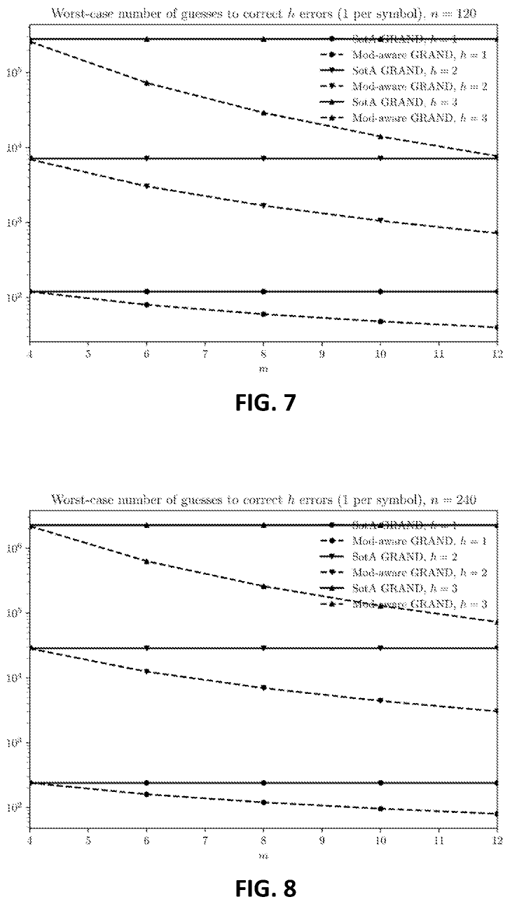

FIGS. 7 and 8 show examples of graphs of the number of guesses needed, in the worst case, to correct h errors as a function of the modulation order for two different block lengths, n=120 for FIG. 7 and n=240 for FIG. 8. The graphs show results for example techniques according to this disclosure (labelled as mod-aware GRAND) and the state-of-the-art (SotA) GRAND, which is unaware of modulation and labeling. Irrespective of the block length, the saving factor increases as the modulation order increases and the number of errors to be corrected increases. Observe that the number of computations, in the worst case, is never larger than that required by GRAND. Therefore, implementing example embodiments of this disclosure cannot be detrimental compared to SotA GRAND, and for high-order modulations, may provide about one order of magnitude saving in computational complexity.

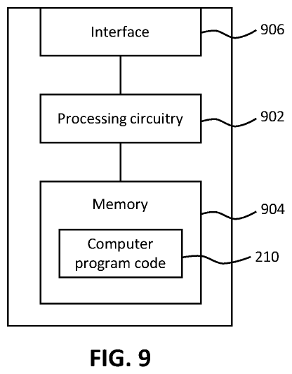

FIG. 9 is a schematic of an example of an apparatus 900 for correcting one or more errors in a received word. The apparatus 900 comprises processing circuitry 902 (e.g. one or more processors) and a memory 904 in communication with the processing circuitry 902. The memory 904 contains instructions, such as computer program code 810, executable by the processing circuitry 902. The apparatus 900 also comprises an interface 906 in communication with the processing circuitry 902. Although the interface 906, processing circuitry 902 and memory 904 are shown connected in series, these may alternatively be interconnected in any other way, for example via a bus.

In one embodiment, the memory 904 contains instructions executable by the processing circuitry 902 such that the apparatus 900 is operable/configured to modify a first symbol label in the received word to a first alternative symbol label corresponding to a symbol in a symbol constellation that is one of a closest one or more symbols to a symbol corresponding to the first symbol label to form a first modified word, and determine whether the first modified word is a valid codeword. In some examples, the apparatus 900 is operable/configured to carry out the method 100 described above with reference to FIG. 1.

It should be noted that the above-mentioned examples illustrate rather than limit the invention, and that those skilled in the art will be able to design many alternative examples without departing from the scope of the appended statements. The word “comprising” does not exclude the presence of elements or steps other than those listed in a claim, “a” or “an” does not exclude a plurality, and a single processor or other unit may fulfil the functions of several units recited in the statements below. Where the terms, “first”, “second” etc. are used they are to be understood merely as labels for the convenient identification of a particular feature. In particular, they are not to be interpreted as describing the first or the second feature of a plurality of such features (i.e. the first or second of such features to occur in time or space) unless explicitly stated otherwise. Steps in the methods disclosed herein may be carried out in any order unless expressly otherwise stated. Any reference signs in the statements shall not be construed so as to limit their scope.

1. A method of correcting one or more errors in a received word using GRAND, the received word comprising one or more symbol labels, the method comprising:
modifying a first symbol label in the received word to a first alternative symbol label corresponding to a symbol in a symbol constellation that is one of a closest one or more symbols to a symbol corresponding to the first symbol label to form a first modified word, the closest one or more symbols to the symbol corresponding to the first symbol label comprising one or both of:
one or both symbols vertically adjacent to the symbol corresponding to the first symbol label in the symbol constellation; and
one or both symbols horizontally adjacent to the symbol corresponding to the first symbol label in the symbol constellation; and
determining whether the first modified word is a valid codeword.

2. The method of claim 1, wherein the closest one or more symbols to the symbol corresponding to the first symbol label comprise a plurality of symbols closest to the symbol corresponding to the first symbol label, and the method comprises:
if the first modified word is not a valid codeword, for each of one or more further symbols of the plurality of symbols closest to the symbol corresponding to the first symbol label, modifying the first symbol label in the received word to a respective further alternative symbol label corresponding to the further symbol to form a respective further modified word, and determining whether the respective further modified word is a valid codeword.

3. The method of claim 2, wherein modifying the first symbol label to the first alternative symbol label and each of the further alternative symbol labels is performed in an order based on soft decoding information for the first symbol label.

4. The method of claim 3, wherein the order comprises an order of decreasing likelihood for each of the first alternative symbol label and the further alternative symbol labels.

5. The method of claim 2, wherein modifying the first symbol label to the first alternative symbol label and each of the further alternative symbol labels is performed in an order based on decreasing probability that one or more respective bits in the first symbol label modified to the first alternative symbol label and each of the further alternative symbol labels correspond to the one or more errors in the received word.

6. The method of claim 2, comprising, if each of the further modified words is not a valid codeword, for each of one or more additional symbol labels in the symbol constellation, modifying the first symbol label in the received word to the additional symbol label to form a respective further modified word, and determining whether the respective modified word is a valid codeword.

7. The method of claim 1, comprising, if the first modified word is not a valid codeword, for each of one or more additional symbol labels in the symbol constellation, modifying the first symbol label in the received word to the additional symbol label to form a respective further modified word, and determining whether the respective further modified word is a valid codeword.

8. The method of claim 1, wherein the received word comprises a plurality of symbol labels, and the method comprises:
if the first modified word is not a valid codeword, for each of one or more further symbol labels in the received word, modifying the further symbol label to a respective alternative symbol label corresponding to a symbol in the symbol constellation that is one of a closest one or more symbols to a symbol corresponding to the further symbol label to form a respective further modified word, and determining whether the respective further modified word is a valid codeword.

9. The method of claim 8, wherein the closest one or more symbols to the symbol corresponding to the further symbol label comprise a plurality of symbols closest to the symbol corresponding to the further symbol label, and the method comprises:
if the further modified word is not a valid codeword, for each of one or more further symbols of the plurality of symbols closest to the symbol corresponding to the further symbol label, modifying the further symbol label in the received word to a respective further alternative symbol label corresponding to the further symbol to form a respective further modified word, and determining whether the respective further modified word is a valid codeword.

10. The method of claim 9, wherein modifying the further symbol label to the alternative symbol label and each of the further alternative symbol labels is performed in an order based on soft decoding information for the further symbol label.

11. The method of claim 10, wherein the order comprises an order of decreasing likelihood for each of the alternative symbol label and the further alternative symbol labels.

12. The method of claim 9, wherein modifying the further symbol label to the alternative symbol label and each of the further alternative symbol labels is performed in an order based on decreasing probability that one or more respective bits in the further symbol label modified to the alternative symbol label and each of the further alternative symbol labels correspond to the one or more errors in the received word.

13. The method of claim 9, comprising, if each of the further modified words is not a valid codeword, for each of one or more additional symbol labels in the symbol constellation, modifying the further symbol label in the received word to the additional symbol label to form a respective further modified word, and determining whether the respective further modified word is a valid codeword.

14. The method of claim 8, wherein the closest one or more symbols to the symbol corresponding to the further symbol label comprises one or both of:
one or both symbols vertically adjacent to the symbol corresponding to the further symbol label in the symbol constellation; and
one or both symbols horizontally adjacent to the symbol corresponding to the further symbol label in the symbol constellation.

15. (canceled)

16. The method of claim 1, wherein modifying the first symbol label in the received word to the first alternative symbol label comprises:
generating a noise bit sequence; and
subtracting the noise bit sequence from the received word to form the first modified word.

17. The method of claim 1, wherein the closest one or more symbols to the symbol corresponding to the first symbol label comprise a subset of symbols in the symbol constellation.

18. The method of claim 1, wherein the symbol constellation comprises a phase shift keying (PSK) constellation, a Quadrature Amplitude Modulation (QAM) constellation or a cross constellation.

19.-21. (canceled)

22. An apparatus for correcting one or more errors in a received word using GRAND, the apparatus comprising a processor and a memory, the memory containing instructions executable by the processor such that the apparatus is operable to:
modify a first symbol label in the received word to a first alternative symbol label corresponding to a symbol in a symbol constellation that is one of a closest one or more symbols to a symbol corresponding to the first symbol label to form a first modified word, the closest one or more symbols to the symbol corresponding to the first symbol label comprising one or both of:
one or both symbols vertically adjacent to the symbol corresponding to the first symbol label in the symbol constellation; and
one or both symbols horizontally adjacent to the symbol corresponding to the first symbol label in the symbol constellation; and
determine whether the first modified word is a valid codeword.

23. The apparatus of claim 22, wherein the closest one or more symbols to the symbol corresponding to the first symbol label comprise a plurality of symbols closest to the symbol corresponding to the first symbol label, and the memory contains instructions executable by the processor such that the apparatus is operable to:
if the first modified word is not a valid codeword, for each of one or more further symbols of the plurality of symbols closest to the symbol corresponding to the first symbol label, modify the first symbol label in the received word to a respective further alternative symbol label corresponding to the further symbol to form a respective further modified word, and determine whether the respective further modified word is a valid codeword.

24. The apparatus of claim 23, wherein modifying the first symbol label to the first alternative symbol label and each of the further alternative symbol labels is performed in an order based on soft decoding information for the first symbol label.

25.-41. (canceled)
